(19) United States
(12) Patent Application Publication
(10) Pub. No.: US 2007/0200176 A1
(43) Pub. Date: Aug. 30, 2007

(54) FORMATION OF SILICIDED SURFACES FOR SILICON/CARBON SOURCE/DRAIN REGIONS

(76) Inventors: Thorsten Kammler, Ottendorf-Okrilla (DE); Patrick Press, Dresden (DE); Rolf Stephan, Dresden (DE); Sven Beyer, Dresden (DE)

Correspondence Address: WILLIAMS, MORGAN & AMERSON, 10333 RICHMOND, SUITE 1100, HOUSTON, TX, 77042, US

(21) Appl. No.: 11/550,631

(22) Filed: Oct. 18, 2006

(30) Foreign Application Priority Data
Feb. 28, 2006 (DE) 10 2006 009 225.2

(51) Int. Cl. H01L 27/12

(52) U.S. Cl. 257/347

(57) ABSTRACT

Formation of a silicide layer on the source/drain regions of a field effect transistor with a channel under tensile strain is disclosed. The strain is originated by the silicon/carbon source/drain regions which are grown by CVD deposition. In order to form the silicide layer, a silicon cap layer is deposited in situ by CVD. The silicon cap layer is then employed to form a silicide layer made of a silicon/cobalt compound. This method allows the formation of a silicide cobalt layer in silicon/carbon source/drain regions, which was until the present time not possible.

### BACKGROUND OF THE INVENTION

1. Field of the Invention

Generally, the present invention relates to the formation of integrated circuits, and, more particularly, to the formation of source/drain regions for field effect transistors with a strained channel region, and to the subsequent formation of silicided layers on these source/drain regions, where the source/drain regions are made of a material that generates a tensile strain in the channel region, as for example silicon/carbon.

2. Description of the Related Art

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, CMOS technology is currently the most promising approach due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source regions.

The conductivity of the channel region, i.e., the drive current capability of the conductive channel, is controlled by a gate electrode formed above the channel region and separated therefrom by a thin insulating layer. The conductivity of the channel region, upon formation of a conductive channel, due to the application of an appropriate control voltage to the gate electrode, depends on the dopant concentration, the mobility of the majority charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the overall conductivity of the channel region substantially determines the performance of the MOS transistors. Thus, the reduction of the channel length, and associated therewith the reduction of the channel resistivity, renders the channel length a dominant design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. One major problem in this respect is the development of enhanced photolithography and etch strategies so as to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control. Hence, reducing the channel length may usually also require reducing the depth of the drain and source regions with respect to the interface formed by the gate insulation layer and the channel region, thereby requiring sophisticated implantation techniques. According to other approaches, epitaxially grown regions are formed with a specified offset to the gate electrode, which are referred to as raised drain and source regions, providing increased conductivity of the raised drain and source regions, while at the same time maintaining a shallow PN junction with respect to the gate insulation layer.

Since the continuous size reduction of the critical dimensions, i.e., the gate length of the transistors, necessitates the adaptation and possibly the new development of highly complex process techniques concerning the above-identified process steps, it has been proposed to also enhance the channel conductivity of the transistor elements by increasing the charge carrier mobility in the channel region for a given channel length, thereby offering the potential for achieving a performance improvement that is comparable with the advance to a future technology node, while avoiding or at least postponing many of the above process adaptations associated with device scaling. One efficient mechanism for increasing the charge carrier mobility is the modification of the lattice structure in the channel region, for instance by creating tensile or compressive stress to produce a corresponding strain in the channel region, which results in a modified mobility for electrons and holes, respectively. For example, creating tensile strain in the channel region increases the mobility of electrons, wherein, depending on the magnitude and direction of the tensile strain, an increase in mobility of 50% or more may be obtained, which, in turn, may directly translate into a corresponding increase in the conductivity. On the other hand, compressive strain in the channel region may increase the mobility of holes, thereby providing the potential for enhancing the performance of P-type transistors. The introduction of stress or strain engineering into integrated circuit fabrication is an extremely promising approach for further device generations, since, for example, strained silicon may be considered as a “new” type of semiconductor material, which may enable the fabrication of fast powerful semiconductor devices without requiring expensive semiconductor materials and manufacturing techniques.

Consequently, in order to generate a stress in the crystal structure of the channel region, different approaches have been proposed, such as the formation of a silicon/germanium layer or of a silicon/carbon layer in or below the channel region, so that the stress is generated by the misfit of lattice spacing between the different layers, or the formation of overlaying layers, spacer elements and the like which possess intrinsic stress and thus generate mechanical strain in the channel region. In other approaches, a strained silicon/germanium layer or a silicon/carbon layer is formed in the drain and source regions of the transistor, so that the strained drain/source regions create a uniaxial strain which propagates into the adjacent silicon channel region. Although the formation of embedded strained layers in the drain and source regions may provide high performance gain, other processes may be affected by the presence of non-silicon material.

For instance, a typical process during the fabrication of MOS transistors is the silicidation of the drain and source regions. During the silicide process, a metal is introduced into the silicon to reduce the resistivity between a contact metal and the source/drain regions. In order to silicide the MOS transistors having source/drain regions, the presence of significant amounts of non-silicon atoms in the source/drain regions may negatively affect the process. For example, the formation of cobalt silicide in the presence of carbon may be difficult and it may result in a non-reliable silicon/metal compound.

In view of the above-described situation, there is a need for a new approach in order to enable the formation of silicided layers for source and drain regions including non-silicon materials, such as carbon.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to one illustrative embodiment of the present invention, a method comprises forming a recess adjacent to a gate electrode of a transistor and forming a semiconductor layer in the recess which produces a tensile strain in the channel region of the transistor. The method further comprises forming a cap layer on the semiconductor layer and forming a silicided layer in the cap layer.

According to another illustrative embodiment of the present invention, a transistor element comprises a strained channel region and source/drain regions formed in a crystalline semiconductor layer, which further comprises a first and a second layer, wherein the first layer generates tensile strain in the strained channel region due to a lattice mismatch between the first layer and the channel region. The second layer comprises a metal silicide.

### BRIEF DESCRIPTION OF THE DRAWINGS

The invention may be understood by reference to the following description taken in conjunction with the accompanying drawings, in which like reference numerals identify like elements, and in which:

FIG. 1 schematically shows a cross-sectional view of a transistor element with a channel region under tensile strain and a silicide layer over the source/drain regions, according to an illustrative embodiment of the present invention;

FIGS. 2a-2e schematically show the fabrication process of a silicide layer for a transistor element with a channel region under tensile strain, wherein the source/drain regions are made of silicon/carbon, according to illustrative embodiments of the present invention;

FIG. 3 schematically shows a cross-sectional view of a transistor element according to an embodiment of the present invention, wherein an intermediate layer is located between the silicide layer and the silicon/carbon layer; and

FIG. 4 schematically shows a cross-sectional view of a transistor element according to an embodiment of the present invention, wherein the transistor channel is under tensile strain originated by the source/drain regions, which are completely embedded in the active layer of the transistor element.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Silicide surfaces are generally formed on the source/drain regions of MOS transistors in order the improve the electrical properties between the source/drain regions of the transistor and the metal contact. Silicide surfaces are metal/semiconductor compound surfaces with a low resistivity in comparison with semiconductor materials. Standard metals used in the formation of silicided surfaces are the group VIII metal (Pt, Pd, Co, Ni) and Ti, which penetrating in the semiconductor layers give origin to the silicides PtSi, Pd₂Si, CoSi₂, NiSi₂ and TiSi₂. Due to their low resistivity, titanium silicide (TiSi₂) and cobalt silicide (CoSi₂) have been the two most widely implemented materials for silicide processes. The silicidation can be a critical process which gives origin to non-stable compounds. This is particularly true if non-silicon materials are present in the semiconductor layer. Examples can be silicon/carbon or silicon/germanium, which are widely used for the fabrication of source/drain regions in MOS transistors with strained channel regions. Here is presented a transistor structure and a method of fabrication of the same which also allows for the formation of silicide surfaces in problematic cases. In a particular embodiment according to this invention, the formation of cobalt silicide above silicon/carbon regions is achieved. At the present stage, no feasible method for the formation of cobalt silicide in silicon/carbon regions is available. The technique according to the present invention can also be advantageously applied to other silicide materials, such as nickel, platinum or other above-mentioned metals, which present similar problems on silicon/carbon, silicon/germanium or other silicon compound surfaces.

Generally, the present invention contemplates a transistor element with a channel region under tensile strain and a silicided layer in the source/drain region in order to improve the contact properties of the transistor element and a method to fabricate the same. In some embodiments, the present invention refers to NMOS transistors where the silicon channel region is under a tensile stress in order to increase the electron mobility in the channel. The tensile stress is generated by the source and drain regions in a uniaxial way. The source and drain regions have, at least partially, a different lattice spacing than the channel region. In some illustrative embodiments, the drain/source regions comprise strained silicon/carbon, which induces the formation of a tensile stress in the silicon channel region. Standard techniques used for the formation of silicided source/drain regions include the deposition of a metal layer, for example cobalt, followed by rapid thermal reaction treatment, which creates a metal-semiconductor compound, such as CoSiₓ. This technique may not be efficiently applied to the present case of silicon/carbon source/drain regions, due to the formation of unstable compounds, thereby preventing the proper silicidation of the surfaces. In order to overcome this problem, a silicon cap layer is selectively deposited over the source/drain regions and is then converted into silicide, wherein, in one embodiment, the cap layer is substantially completely consumed during the silicidation.

This is done by depositing a cobalt layer on the silicon cap layer, followed by a rapid thermal reaction treatment which creates a metal-semiconductor compound from the cobalt layer and the silicon cap layer. The formation of the cap layer and the subsequent silicidation process may not substantially influence the mechanical properties of the embedded silicon/carbon layer in the source/drain regions, thus the stress transfer between the source/drain regions and the channel region remains efficient after the silicidation process.

Although highly advantageous in the context of silicon/carbon strain layers and cobalt/silicon compounds, the employment of a cap layer for the formation of silicided surfaces, according to the present invention, may also be applied to any surface where the direct formation of the silicided surfaces is problematic.

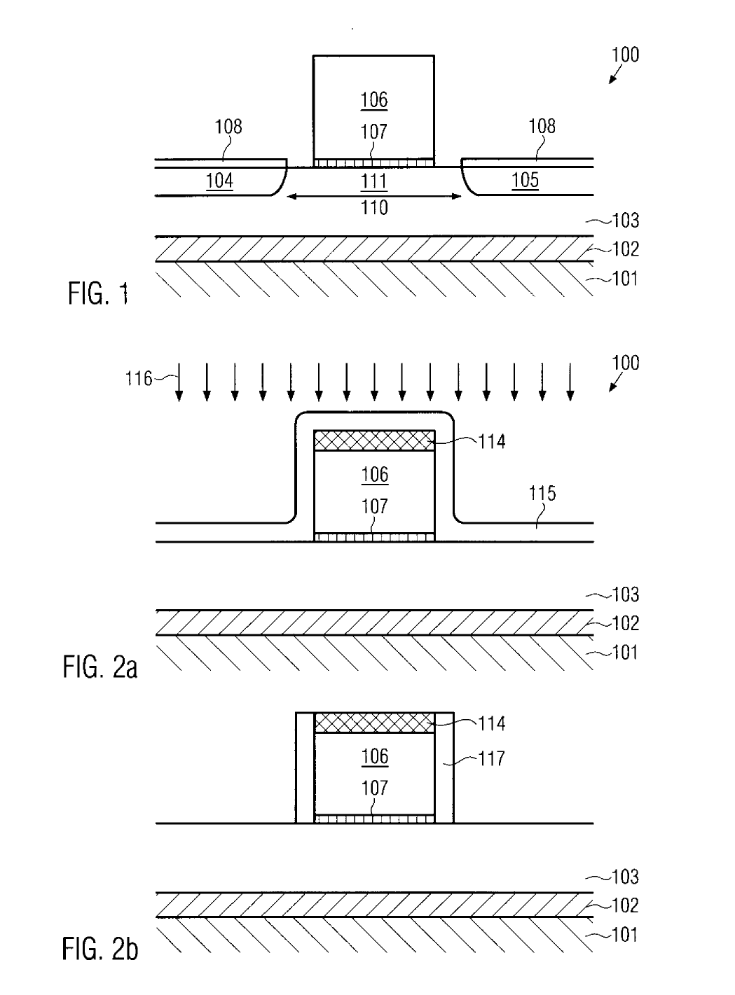

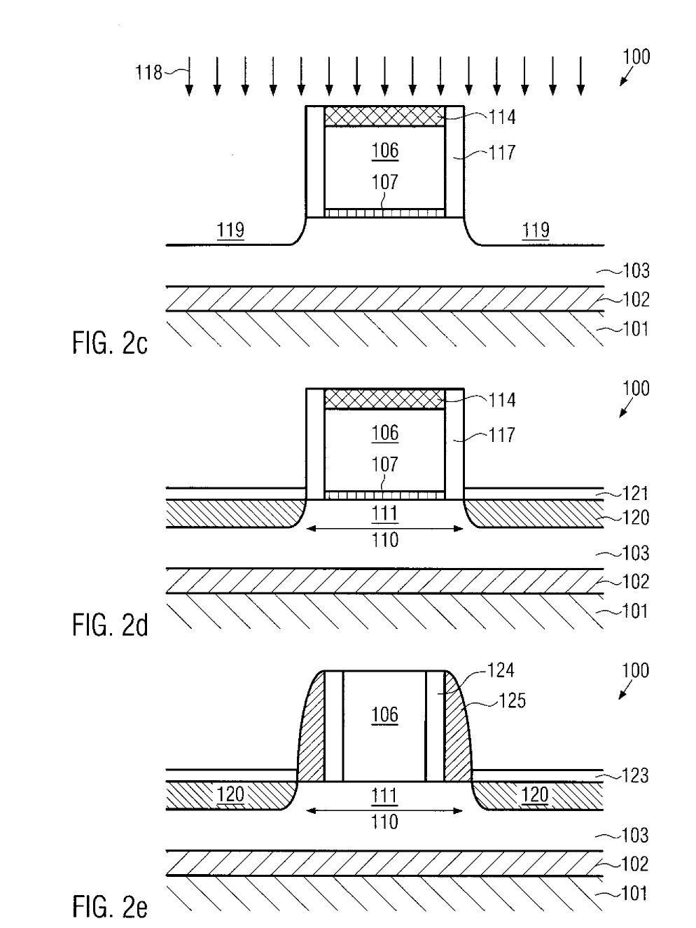

In the following, further illustrative embodiments according to the present invention will be described in more detail with reference to NFET transistors and the relative fabrication methods. The transistor structures according to the different embodiments will be illustrated in FIGS. 1, 3 and 4 and the fabrication processes will be illustrated in FIGS. 2a-2h.

FIG. 1 schematically illustrates a cross sectional view of a MOS transistor 100 according to the present invention. An active region 103 and a portion of the source/drain regions 104, 105 have different lattice spacing so that a strain field 110 is extending from the source and drain regions to the channel region 111 between source and drain. For convenience, the drain/source regions are shown with an epitaxially grown material without any dopant concentration. The same holds true for any extension regions typically formed in the vicinity of the channel region 111. In a particular embodiment of the present invention, part of the source/drain regions 104,105 are made of highly carbon-doped silicon and the active region 103 is made of silicon so that a tensile strain is generated in the channel region 111. The percentage of carbon in the silicon can be 1% or higher. The channel is under tensile strain due to a strain transfer from the source/drain regions to the channel region. Portions of the source/drain regions can be under strain and this strain is then transferred to the channel region. The strain in parts of the source/drain regions can be originated by the presence of the carbon atoms in the lattice structure or it can be originated by the lattice misfit existing between the silicon active region 103 and the silicon carbon present in parts of the source/drain regions or by a combination of both effects. Alternatively, the portions of the source/drain regions can be formed on a relaxed buffer layer (not shown), which is located between the active region 103 and the source/drain regions, so that the source/drain regions are not subject to a strain. The strain in this case is then generated in the channel region by the lattice misfit at the interface between parts of the source/drain regions and the channel region.

The active region 103 is formed on the substrate 101,102. It should be appreciated that the substrate 101, including the insulating layer 102, which may be comprised of silicon dioxide, silicon nitride or any other appropriate insulating material, may represent any SOI-type substrate, wherein this term is to be considered as a generic term for any substrate having at least an insulating portion above which is formed a crystalline semiconductor layer appropriate for the formation of transistor elements therein. The transistor device 100 includes a gate electrode 106, which is separated from the active region 103 by a gate insulation layer 107. A silicided layer 108 is formed on the source and drain regions, in order to have a better contact between the source/drain regions and the metal. In a particular embodiment according to the present invention, as illustrated in FIG. 1, the silicided layer can form raised source/drain regions. Depending on process strategies, an appropriate metal silicide region (not shown) may also be formed in the gate electrode 106, which may have the same or a different composition compared to the silicide regions 108.

A typical process for forming the semiconductor device 100 as shown in FIG. 1 may comprise the following processes as illustrated in FIGS. 2a-2h. The substrate 101, including the insulating layer 102 when an SOI architecture is considered, may receive an appropriate semiconductor layer, such as an undoped or predoped crystalline silicon layer, wherein the silicon layer may be formed by wafer bond techniques or any other well-established techniques for providing SOI substrates. Next, an appropriate dielectric layer may be formed by oxidation and/or deposition followed by the deposition of a gate electrode material, such as polysilicon or predoped polysilicon, which may be accomplished by low pressure chemical vapor deposition (LPCVD) techniques. Thereafter, a cap layer 114 may be formed on top of the gate electrode material 106, wherein the cap layer 114 may also act as an anti-reflective coating (ARC) layer for a subsequently performed lithography process. The cap layer 114 may be comprised of an appropriate material, such as silicon nitride, silicon oxynitride and the like. Moreover, the cap layer may additionally or alternatively act as a hard mask during the subsequent etch processes.

Thereafter, the spacer layer 115 may be deposited on the basis of, for instance, well-established plasma enhanced chemical vapor deposition (PECVD) techniques with a required thickness that substantially determines a desired offset for recesses to be formed within the active region 103 so as to form therein an appropriate semiconductor material for obtaining the desired strain in the channel region 111. A thickness of the spacer layer 115 may be selected in accordance with device requirements, for instance in the range of approximately 50-300 Å, or any other appropriate value that is desired for an offset of a recess to be formed adjacent to the gate electrode 106. After the deposition of the spacer layer 115, the semiconductor device 100 may be subjected to a selective anisotropic etch process 116 to thereby remove the spacer layer 115 from the horizontal portions of the device 100. Corresponding appropriate anisotropic etch recipes are well established in the art and are also typically used for the formation of sidewall spacers as may be used for the implantation and thus for the formation of appropriate lateral dopant profiles of transistor elements.

FIG. 2b schematically shows the semiconductor device 100 after the completion of the anisotropic etch process 116, thereby leaving the spacer elements 117 on sidewalls of the gate electrode 106. As explained above, the corresponding width of the spacers 117 is substantially determined by the thickness of the layer 115 and thus by the corresponding deposition recipe for forming the spacer layer 115. Consequently, the gate electrode 106 is encapsulated by a dielectric material so as to substantially protect the gate electrode 106 during subsequent etch and epitaxial growth processes for forming an embedded strained semiconductor layer in the transistor 100.

FIG. 2c schematically shows the semiconductor device 100 during an anisotropic etch process, indicated as 118, during which a corresponding recess 119 is formed adjacent to the gate electrodes 106. The anisotropic etch process 118 may be designed to exhibit high selectivity between the material, such as silicon, of the active region 103 and the materials of the spacer 117 and the capping layers 114. For instance, highly selective anisotropic etch processes with a moderate selectivity between silicon, silicon dioxide and silicon nitride are well established in the art. In this way, only the silicon material of the active region 103 is etched away while the cap layer 114 and the lateral spacer 117 are not influenced by the etch process 118.

Next, the device 100 may be prepared for a subsequent epitaxial growth process, in which an appropriate semiconductor compound may be deposited in order to form a strained area below the gate electrode 106. Thus, appropriate well-established cleaning processes may be performed to remove any contaminants on exposed silicon surfaces within the recess 119. Thereafter, an appropriate deposition atmosphere is provided on the basis of well-established recipes, wherein, in one embodiment, the deposition atmosphere may be designed to initiate the deposition of a silicon/carbon material. The deposition can be done by chemical vapor deposition (CVD) techniques, in particular employing selective epitaxial growth (SEG). In the selective epitaxial growth of silicon, growth occurs only on the exposed silicon areas of a silicon substrate, taking on the lattice spacing of the underlying substrate. The SEG of silicon on silicon surfaces is a process in which the nucleation and growth of the material on silicon dioxide and silicon nitride is substantially avoided. Applying this technique to the present invention, it is possible to grow silicon/carbon in the recess 119, while substantially no nucleation or growth happens on the cap layer 114 and on the lateral spacer elements 117. It should be appreciated that, during the cavity etch process 118 and during the subsequent epitaxial growth process, the PFET areas of the integrated circuit may be covered by a hard mask on the basis of well-established techniques.

FIG. 2d schematically shows the semiconductor device 100 after the completion of the selective epitaxial growth process, where epitaxially grown semiconductor layers 120 have been deposited within the recess 119. In one illustrative embodiment, the semiconductor layers 120 represent strained semiconductor material, such as silicon/carbon. For example, approximately 1 atomic percent carbon or more may be provided in the silicon/carbon material, thereby forming a compressively strained lattice in the layers 120, which also induces a corresponding uniaxial tensile strain in the respective channel region 111, which is indicated as 110 and which is located below the gate electrode 106. It should be appreciated that the provision of silicon/carbon may be highly advantageous with respect to providing tensile strain in an NMOS transistor. However, in other embodiments, other semiconductor compounds may be deposited.

Next, after the formation by selective epitaxial growth of parts of the source/drain regions, a silicide layer has to be formed in a later stage in order to reduce the electrical resistance between the transistor element and the metal connection. To enable the formation of an appropriate silicide layer, a semiconductor cap layer 121 may be formed on portions of the source/drain region, as showed in FIG. 2d. In a particular embodiment, the cap layer is a silicon layer. The deposition is done by CVD, in particular using selective epitaxial growth, as also for the previous part of the source/drain regions, so that, in the case of silicon, the cap layer 121 is formed only on the source/drain region and substantially no growth takes place on the lateral spacer elements 117 and cap layer 114. In this way, the process can be done without the employment of a mask. The silicon/carbon portions of the source/drain regions and the cap layer 121 can be grown in situ. Furthermore, the source/drain region as well as the cap layer can be doped in situ.

Thereafter, the cap layer 114 on the gate electrode 106 and the sidewall 117 are removed. To this end, well-established highly selective etch processes may be performed, for instance on the basis of hot phosphoric acid, when the spacers 117 and the capping layers 114 are substantially comprised of silicon nitride.

FIG. 2e schematically shows the semiconductor device 100 in a further advanced stage, in which a first spacer 124 and a second spacer 125 are formed on the sidewalls of the gate electrode 106. In some embodiments, the spacers 124, 125 can be used for the subsequent formation of drain and source and extension regions by ion implantation. As previously explained, for convenience, any doped regions are not shown.

Thereafter, a metal layer is deposited on the cap layer 121. In a particular embodiment, the metal layer can be a cobalt metal layer. The metal layer can be deposited to a thickness between about 30-300 Å using either sputtering, CVD techniques or any other appropriate deposition technique. Then, a first rapid thermal anneal of the deposited metal layer is performed, creating a layer of silicided metal. Afterward, the unreacted metal is removed from the surface by applying a selective etch and finally a second rapid thermal anneal of the deposited metal layer is performed, creating a low-resistivity silicided layer. In the case where the metal layer is a cobalt layer, the final silicided layer is made of a silicon/cobalt compound CoSiₓ. In a particular embodiment in accordance with the present invention, the semiconductor cap layer 121 is a “sacrificial layer” and it is substantially totally converted in a silicide layer.

Typically during the silicidation process, a silicide layer may also be formed on the top of the gate electrode in order to improve the electrical properties of the device. In some embodiments, the formation of a silicide layer on the gate electrode may be avoided and may be formed on a later stage. This is possible by keeping the cap layer 114 shown in FIG. 2d, so that thereon the metal layer does not form a silicide layer and can be removed.

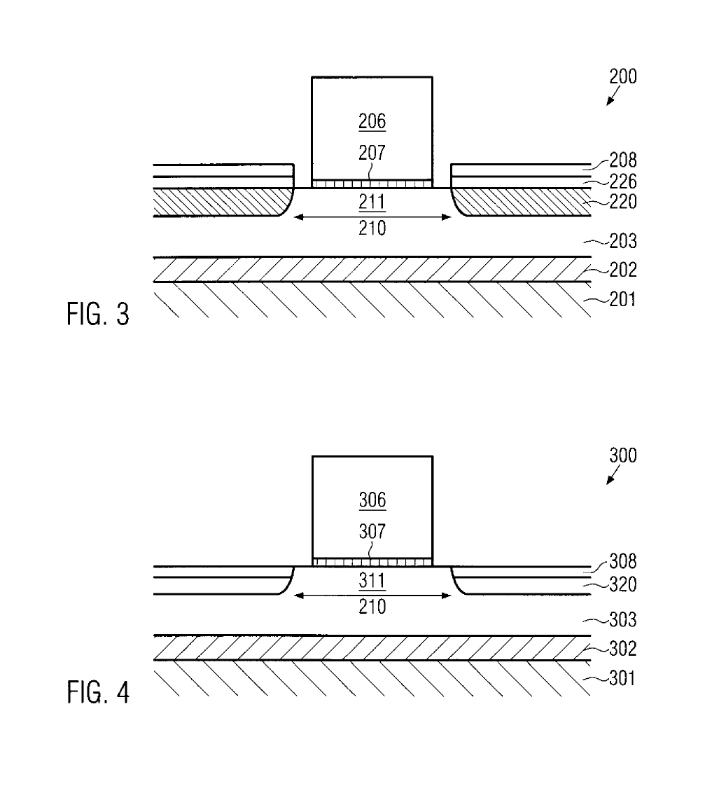

FIG. 3 schematically shows an alternative embodiment of a transistor element 200 according to the present invention with source/drain regions including three different layers. The structure of the present embodiment is similar to the one shown in FIG. 1. The active region 203 is formed on the substrate 201, 202. The substrate 201 and the insulating layer 202, which may be comprised of silicon dioxide, silicon nitride or any other appropriate insulating material, represent any SOI-type substrate. The active region 203 and portions of the source/drain regions 220 have the same crystal structure but different lattice spacing so that a strain field 210 is extending from the source and drain regions to the channel region 211 between source and drain. In a particular embodiment, parts of the source/drain regions 204, 205 are made of highly carbon-doped silicon and the active region 203 is made of silicon so that a tensile strain is generated in the channel region 211.

A silicided layer 208 is formed on a semiconductor layer, which is located on parts of the source/drain regions. The semiconductor layer is preferentially a doped silicon layer. In this embodiment, the source/drain regions comprise three different layers and are, as also in the embodiment depicted in FIG. 1, raised regions.

The present embodiment has the advantage that the semiconductor layer located between the silicided layer 208 and the strained region of the source/drain regions can prevent undesired spikes from the silicide layer penetrating in the bottom layer and eventually in the active region which could cause the malfunction of the transistor element.

A typical process for forming the semiconductor device 200 as shown in FIG. 3 is similar to the process described for the transistor element 100 in FIGS. 2a-2e. The differences are in the formation of the silicide layer. According to the present embodiment, the quantity of metal layer deposited on the cap layer is not sufficient to completely silicide the cap layer itself. In this way, an intermediate layer remains between the silicide layer and the rest of the source/drain regions. In a particular embodiment, the metal layer is a cobalt layer.

FIG. 4 schematically shows an alternative embodiment of a transistor element 300 according to the present invention where also the silicide layer is grown in the recess 319 (not shown in figure). The structure of the present embodiment is similar to the one shown in FIG. 1. The active region 303 is formed on the substrate 301, 302. The substrate 301 and the insulating layer 302, which may be comprised of silicon dioxide, silicon nitride or any other appropriate insulating material, represent any SOI-type substrate. The active region 303 and portions of the source/drain regions 320 have different crystal structure so that a strain field 310 is extending from parts of the source and drain regions to the channel region 311 between source and drain. In a particular embodiment, portions of the source/drain regions 304, 305 are made of highly carbon-doped silicon and the active region 303 is made of silicon so that a tensile strain is generated in the channel region 311.

According to the present embodiments the strained layers 304, 305 do not fill completely the recess 319 (not shown in figure). On the layers 304, 305 is then formed a silicide layer which fills the recess completely. A typical process for forming the semiconductor device 300 as shown in FIG. 4 is similar to the process described for the transistor element 100 in FIGS. 2a-2e. The differences are in the formation of the recess, in particular in the depth of the recess, and in the formation of the silicon/carbon layer and the silicide layer, so that the cap layer can be deposited in the recess itself, so that it is then totally filled by the cap layer. Knowing the silicidation rate, it is then possible to deposit enough metal material so that the cap layer is totally silicided. In a particular embodiment in accordance with the present invention, the cap layer is a silicon layer and the metal layer is cobalt.

Summarizing, the present invention is in general directed to a technique to form silicided layers in the case of field effect transistors where the source/drain regions are made of silicon including a certain amount of carbon, for example Si:C with the carbon percentage around 1% or higher, which may presently be very difficult because the carbon hinders the silicidation with cobalt. In the case of Si:C (highly C-doped silicon) embedded in the source/drain regions of NFET transistors, the Si:C is epitaxially deposited by CVD processes. The present invention features an Si-cap layer which may be in situ grown after the Si:C deposition with a thickness which matches, in some embodiments, the wanted silicide thickness. In these embodiments, the Si-cap layer is “sacrificial” and substantially totally consumed to form the silicide after processing. The mechanical properties of the embedded Si:C layer may not be substantially corrupted by the Si-cap layer. Stress transfer into the channel is still obtained in a highly efficient manner. Further, both Si:C and Si-cap can be deposited in situ doped which ensures good contact and extension resistance.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a recess adjacent to a gate electrode of a transistor;
forming a semiconductor layer in said recess which produces a tensile strain in the channel region of said transistor;
forming a cap layer on said semiconductor layer; and
forming a silicided layer in said cap layer.

2. The method of claim 1, wherein said cap layer is formed by selective epitaxial growth.

3. The method of claim 1, wherein said semiconductor layer in said recess is formed by selective epitaxial growth.

4. The method of claim 1, wherein said semiconductor layer in said recess and said cap layer are grown in situ.

5. The method of claim 1, wherein said cap layer is formed by deposition of a silicon layer.

6. The method of claim 1, wherein forming of said silicided layer comprises the deposition of a metal layer.

7. The method of claim 6, wherein said deposition of said metal layer is followed by a rapid thermal anneal.

8. The method of claim 6, wherein said metal layer is a cobalt layer.

9. The method of claim 1, wherein said semiconductor layer in said recess is formed by selective epitaxial growth.

10. The method of claim 1, wherein said cap layer is substantially completely converted in a silicide.

11. The method of claim 1, wherein part of said cap layer is not silicided.

12. The method of claim 1, wherein said cap layer can be in situ doped.

13. The method of claim 1, wherein said silicided layer can be in situ doped.

14. The method of claim 1, wherein said semiconductor layer is a silicon/carbon layer with approximately 1 atomic percent carbon or more.

15. A transistor element, comprising:
a strained channel region; and
source/drain regions formed in a crystalline semiconductor layer and comprising a first and a second layer, said first layer generating tensile strain in said strained channel region due to the lattice mismatch between said first layer and said channel region and second layer being silicided.

16. The transistor element of claim 15, wherein said source/drain regions are raised regions.

17. The transistor element of claim 15, wherein said first layer comprises silicon and carbon.

18. The transistor element of claim 17, wherein the percentage of carbon in said first layer is 1% or higher.

19. The transistor element of claim 15, wherein said second layer comprises a silicon cobalt compound.

20. The transistor element of claim 15, wherein said second layer has an amorphous structure.

21. The transistor element of claim 15, wherein said transistor is an N-type field effect transistor.

22. The transistor element of claim 15, wherein the source and drain regions comprise a third layer located between the first and the second layers.

23. The transistor element of claim 22, wherein said third layer is a silicon layer.
